(19) United States
(12) Patent Application Publication
(10) Pub. No.: US 2015/0162500 A1
(43) Pub. Date: Jun. 11, 2015

(54) TRANSPARENT ELECTRODE AND METHOD FOR FORMING TRANSPARENT ELECTRODE

(71) Applicant: KOREA UNIVERSITY RESEARCH AND BUSINESS FOUNDATION, Seoul (KR)

(72) Inventors: Tae Geun Kim, Seongnam-si (KR); Min Ju Yun, Cheongju-si (KR)

(21) Appl. No.: 14/403,839

(22) PCT Filed: May 22, 2013
(86) PCT No.: PCT/KR2013/004490

§ 371 Date: Nov. 25, 2014

(30) Foreign Application Priority Data
May 25, 2012 (KR) 10-2012-0055854

(51) Int. Cl. H01L 33/42; H01L 33/14; H01L 33/38

(52) U.S. Cl. CPC H01L 33/42; H01L 33/387; H01L 33/14; H01L 2933/0016

(57) ABSTRACT

Provided are a transparent electrode and a method for forming the transparent electrode. First electrodes having high conductivity are formed with a pattern on the semiconductor layer to be in ohmic contact with the semiconductor layer where the transparent electrode is to be formed, and second electrodes having high transmittance with respect to light in a UV wavelength range as well as in a visible wavelength range are formed so that spaces between the first electrodes formed with the pattern are filled with second electrodes, so that it is possible to obtain a transparent electrode having high transmittance with respect to light in a UV wavelength range as well as in a visible wavelength range and good ohmic characteristic with respect to a semiconductor layer.

### BACKGROUND OF THE INVENTION

1. Field of the Invention

The present invention relates to an electrode and a method for forming an electrode, and more particularly, to a transparent electrode and a method for forming a transparent electrode.

2. Description of the Related Art

Transparent electrodes have been used in various application fields such as LEDs, solar cells, medical UV sterilizers, and fisheries, and the application fields and their demands have been gradually increased. Particularly, the transparent electrodes have been actively used in the LED field. The transparent electrode technique currently applied to the LEDs is mainly an ITO (Indium Tin Oxide) based technique which can be applied to a visible wavelength range of 400 nm to 800 nm and a UV wavelength range of 365 nm to 400 nm in the entire UV wavelength range of 10 nm to 400 nm.

Recently, demands for UV LEDs generating light in a UV wavelength range has been greatly increased. However, a transparent electrode having high conductivity and high transmittance in the UV wavelength range has not been developed. Therefore, it is difficult to commercialize the semiconductor devices such as a UV LED using light in a UV wavelength range.

For example, in the case of a UV LED where an ITO transparent electrode which is currently actively used is formed, most of light in a UV wavelength range of 10 nm to 320 nm generated in an activation layer is absorbed by an ITO layer, so that only about 1% of the light can be transmitted through the ITO layer to be extracted to an external portion.

FIG. 1A is a graph illustrating transmittance and ohmic characteristic (conductivity characteristic) in the case where an ITO transmittance electrode is formed on a p-GaN semiconductor layer in the related art. In the graph, transmittance of the ITO transparent electrode which is subject to thermal treatment at a temperature of 200° C. to 700° C. is illustrated, and ohmic characteristic measured by using a TLM (transfer length method) pattern having an interval of about 2 μm are illustrated.

As illustrated in FIG. 1A, the ITO transparent electrode has good ohmic characteristic. Although the ITO transparent electrode has transmittance of 80% or more with respect to the light in a wavelength range of 400 nm or more, the transmittance is greatly decreased with respect to the light having a short wavelength in the UV wavelength range. Particularly, the transmittance is decreased to 20% or less with respect to the light having a short wavelength in the UV wavelength range of 300 nm or less.

In the related art, in order to improve the transmittance characteristic with respect to the light in the UV wavelength range, a Ga₂O₃ transparent electrode is disclosed. FIG. 1B is a graph illustrating transmittance and ohmic characteristic in the case where a Ga₂O₃ transparent electrode is formed on a p-GaN semiconductor layer in the related art. As illustrated in FIG. 1B, although the Ga₂O₃ transparent electrode has good transmittance characteristic with respect to the light in a wavelength range of 300 nm or less, the ohmic characteristic thereof is very bad, so that Ga₂O₃ is not appropriate for the transparent electrode.

In order to solve the above problem, in the related art, a metal electrode pad is directly formed on a semiconductor layer such as p-AlGaN instead of forming the transparent electrode on the semiconductor layer. However, the metal and the semiconductor layer are not in ohmic contact to each other because of a large difference in work function between the metal and the semiconductor layer, and current is concentrated on a metal electrode pad, but current is not supplied into the entire activation layer, so that an amount of the light generated by the activation layer is greatly decreased.

In order to solve the above problem, various researches have been made, but a transparent electrode having high conductivity and high transmittance in a UV wavelength range has not yet been developed. This is because conductivity and transmittance of a material is basically in trade-off relationship. Since a material having high transmittance in a UV wavelength range has a large band gap, the conductivity thereof is too low to be used as an electrode, and the material is not in ohmic contact with a semiconductor material, so that it is difficult to use the above material as an electrode.

As an example of a technique for solving the above problem, a technique where a transparent electrode is constructed with a sliver (Ag) thin film is disclosed in Korean Patent Application No. 10-2007-0097545. However, in the related art, in the case where the transparent electrode is formed by using Ag, it is very difficult to deposit a thin silver layer on a semiconductor layer so that the thin sliver layer is in ohmic contact with the semiconductor layer. In addition, although a thin silver layer is deposited on the semiconductor layer, as illustrated in the graph of FIG. 4 of the above Patent Document, with respect to the light in a wavelength range 420 nm or less, the transmittance is greatly decreased to 80% or less; and with respect to the light in a wavelength range 380 nm or less, the transmittance is decreased to 50% or less. Therefore, the transmittance in the above-described technique has no difference from the transmittance of the ITO transparent electrode in the related art, and thus, it is difficult to improve the transmittance in a UV wavelength range up to a practical level.

### SUMMARY OF THE INVENTION

The present invention is to provide a transparent electrode having high transmittance and high conductivity with respect to light having a short wavelength in a UV wavelength range as well as in a visible wavelength range and having good ohmic contact characteristic with respect to a semiconductor layer and a method for forming the transparent electrode.

According to an aspect of the present invention, there is provided a transparent electrode including first and second electrodes which are in contact with one surface of a semiconductor layer and have different transmittance and conductivity.

In addition, in the above aspect, the conductivity of the first electrode may be higher than that of the second electrode, and the transmittance of the second electrode may be higher than that of the first electrode.

In addition, in the above aspect, the first electrodes may be formed with a certain pattern, and the second electrodes may be formed so that spaces between first electrodes are filled with the second electrodes.

In addition, in the above aspect, the first electrodes may be formed with a pattern where a plurality of conductive rods is arranged at a certain interval.

In addition, in the above aspect, the first electrodes may be formed with a lattice pattern.

In addition, in the above aspect, the transparent electrode may further include a current spreading layer which is formed on a surface of the transparent electrode which is in contact with the semiconductor layer, wherein the first electrodes and the second electrodes are formed to be in contact with the current spreading layer.

In addition, in the above aspect, the current spreading layer may be formed on surfaces of the first electrodes, and the second electrodes may be formed so that the second electrodes are in contact with the current spreading layer and spaces between the first electrodes are filled with the second electrodes.

In addition, in the above aspect, the current spreading layer may be formed by using CNT (carbon nano tube) or graphene.

In addition, in the above aspect, the transparent electrode may further include a current spreading layer which is formed on surfaces of the first electrodes which are in contact with the semiconductor layer and on surface of the semiconductor layer, wherein the second electrodes are formed so that the second electrodes are in contact with the current spreading layer and spaces between the first electrodes are filled with the second electrodes.

In addition, in the above aspect, the first electrodes may be formed in a direction perpendicular to the semiconductor layer to be in contact with the semiconductor layer, and the second electrodes may be formed to be in contact with the semiconductor layer so that spaces between the first electrodes are filled with the second electrodes.

According to another aspect of the present invention, there is provided a semiconductor device including the transparent electrode disclosed above.

According to still another aspect of the present invention, there is provided a method for forming a transparent electrode, including: (a) forming first electrodes; and (b) forming second electrodes having transmittance and conductivity which are different from those of the first electrodes.

In addition, in the above aspect, the conductivity of the first electrode may be higher than that of the second electrode, and the transmittance of the second electrode may be higher than that of the first electrode.

In addition, in the above aspect, in the (a) forming of the first electrodes, the first electrodes may be formed with a certain pattern, and in the (b) forming of the second electrodes, the second electrodes may be formed so that spaces between first electrodes are filled with the second electrodes.

In addition, in the above aspect, in the (a) forming of the first electrodes, the first electrodes may be formed with a pattern where a plurality of conductive rods is arranged at a certain interval.

In addition, in the above aspect, in the (a) forming of the first electrodes, the first electrodes may be formed with a lattice pattern.

In addition, in the above aspect, the method may further include, before the (a) forming of the first electrodes, forming a current spreading layer on a surface of the transparent electrode which is in contact with the semiconductor layer, wherein the first electrodes and the second electrodes are formed to be in contact with the current spreading layer.

In addition, in the above aspect, in the (a) forming of the first electrodes, after the first electrodes may be formed to be in contact with the current spreading layer, the current spreading layer is additionally formed on surfaces of the first electrodes, and in the (b) forming of the second electrodes, the second electrodes may be formed so that the second electrodes are in contact with the current spreading layer and spaces between the first electrodes are filled with the second electrodes.

In addition, in the above aspect, the current spreading layer may be formed by using CNT or graphene.

In addition, in the above aspect, in the (a) forming of the first electrodes, the first electrodes may be formed to be in contact with the semiconductor layer; the method may further include, between the (a) forming of the first electrode and the (b) forming of the second electrode, forming a current spreading layer on the surfaces of the first electrodes and on the surface of the semiconductor layer; and in the (b) forming of the second electrodes, the second electrodes may be formed so that the second electrodes are in contact with the current spreading layer and spaces between the first electrodes are filled with the second electrodes.

In addition, in the above aspect, in the (a) forming of the first electrodes, the first electrodes may be formed in a direction perpendicular to the semiconductor layer to be in contact with the semiconductor layer, and in the (b) forming of the second electrodes, the second electrodes may be formed to be in contact with the semiconductor layer so that spaces between the first electrodes are filled with the second electrodes.

According to an embodiment of the present invention, first electrodes having high conductivity are formed with a pattern on the semiconductor layer to be in ohmic contact with the semiconductor layer where the transparent electrode is to be formed, and second electrodes having high transmittance with respect to light in a UV wavelength range as well as in a visible wavelength range are formed so that spaces between the first electrodes formed with the pattern are filled with second electrodes, so that it is possible to obtain a transparent electrode having high transmittance with respect to light in a UV wavelength range as well as in a visible wavelength range and good ohmic characteristic with respect to a semiconductor layer.

In addition, according to another embodiment of the present invention, a current spreading layer formed by using CNT or graphene having high conductivity and high transmittance is formed as a thin film on a semiconductor layer, and the above-described first and second electrodes are formed on the current spreading layer, so that it is possible to obtain a transparent electrode having good current spreading efficiency in added to high transmittance and good ohmic characteristic.

In addition, according to still another embodiment of the present invention, first electrodes which have high conductivity and are in ohmic contact with a semiconductor layer where a transparent electrode is to be formed are formed with a pattern on the semiconductor layer, a current spreading layer formed by using CNT or graphene having high conductivity and high transmittance is formed as a thin film on surfaces of the first electrodes and a surface of the semiconductor layer, and second electrodes having high transmittance with respect to light in a UV wavelength range as well as in a visible wavelength range are formed on the current spreading layer so that spaces between the first electrodes are filled with the second electrodes, it is possible to obtain a transparent electrode having good ohmic characteristic with respect to the semiconductor layer, high transmittance with respect to the light in a UV wavelength range as well as in a visible wavelength range, and good current spreading efficiency.

In addition, according to further still another embodiment of the present invention, as a combination of the above embodiments, a current spreading layer is formed on a semiconductor layer, first electrodes are formed with a pattern on the current spreading layer, a current spreading layer is additionally formed on surfaces of the first electrodes, and second electrodes are formed so that spaces between the first electrodes are filled with the second electrodes, so that it is possible to obtain a transparent electrode having better ohmic characteristic with respect to the semiconductor layer, high transmittance with respect to light in a UV wavelength range as well as in a visible wavelength range, and good current spreading efficiency.

### BRIEF DESCRIPTION OF THE DRAWINGS

The above and other features and advantages of the present invention will become more apparent by describing in detail exemplary embodiments thereof with reference to the attached drawings in which:

FIG. 1A is a graph illustrating transmittance and ohmic characteristic in the case where an ITO transmittance electrode is formed on a p-GaN semiconductor layer in the related art;

FIG. 1B is a graph illustrating transmittance and ohmic characteristic in the case where a Ga₂O₃ transparent electrode is formed on a p-GaN semiconductor layer in the related art;

FIG. 2A is a diagram illustrating a configuration of a transparent electrode according to an embodiment of the present invention and a configuration of a semiconductor device including the transparent electrode;

FIG. 2B is a diagram illustrating a configuration of a transparent electrode according to another embodiment of the present invention and a configuration of a semiconductor device including the transparent electrode;

FIG. 2C is a diagram illustrating cross sections of transparent electrodes according to other modified examples of the present invention;

FIG. 3A is a graph illustrating measured data of transmittance of the transparent electrodes according to the embodiments and modified examples of the present invention;

FIG. 3B is a graph illustrating measured data of ohmic characteristic of the transparent electrodes according to the embodiments and modified examples of the present invention; and

FIG. 4 is a diagram illustrating a method for forming the transparent electrodes illustrated in FIGS. 2A and 2B.

### DETAILED DESCRIPTION OF THE INVENTION

Hereinafter, exemplary embodiments of the present invention will be described with reference to the attached drawings.

It should be noted that the present invention is applied to all the transparent electrodes (including transparent electrodes for OLEDs, transparent electrodes for solar cells, transparent electrodes for LEDs, and the like) which are in contact with a semiconductor layer, and the below-described embodiments are provided to explain the present invention.

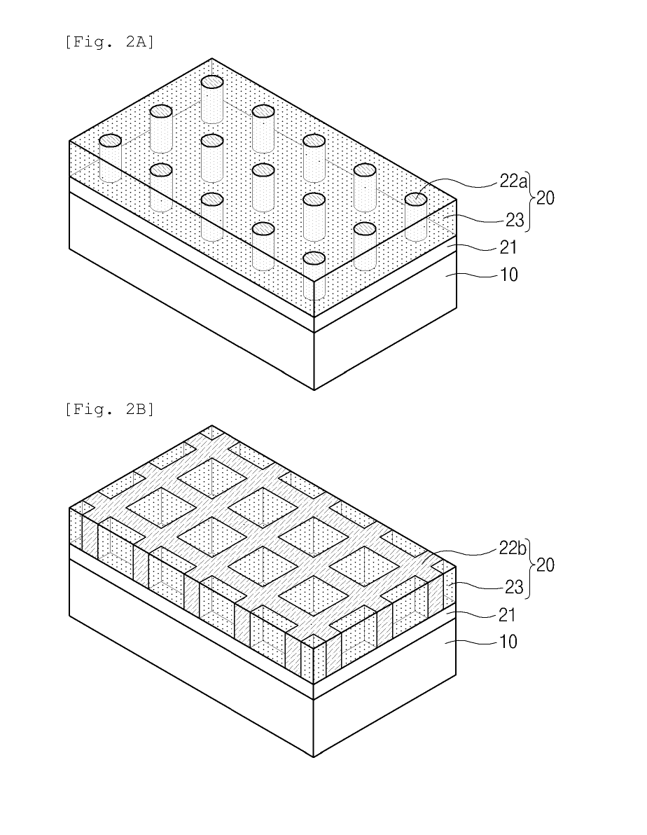

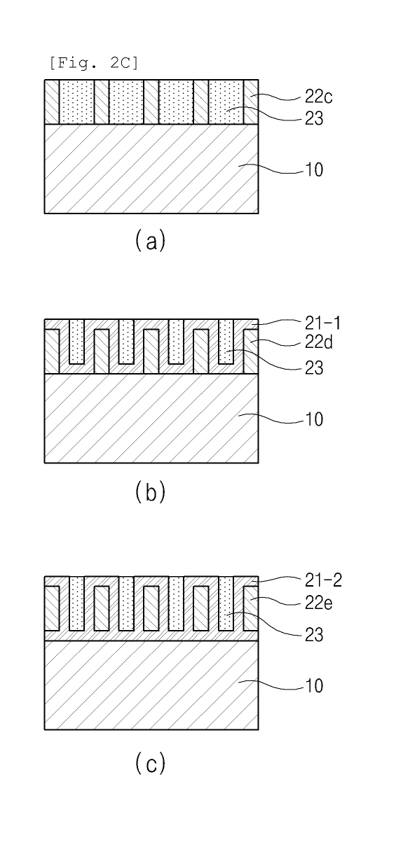

FIG. 2A is a diagram illustrating a configuration of a transparent electrode according to an embodiment of the present invention and a configuration of a semiconductor device including the transparent electrode.

Referring to FIG. 2A, a semiconductor device including a transparent electrode 20 according to the embodiment of the present invention is configured to include a semiconductor layer 10 and the transparent electrode 20 which is formed on the semiconductor layer 10. The transparent electrode 20 according to the embodiment of the present invention is configured to include a current spreading layer 21 which is formed on the semiconductor layer 10 and a first electrode 22a and a second electrode 23 which are formed on the current spreading layer 21.

The current spreading layer 21 is configured to connect the first electrodes to each other in order to improve current spreading efficiency. Therefore, it is preferable that the current spreading layer 21 is formed by using CNT (carbon nano tube) or graphene having high transmittance and high conductivity, and it is preferable that the current spreading layer 21 is formed with a thickness enough to connect the first electrodes 22a to each other and as thin as possible so as not to deteriorate the transmittance. Therefore, in the embodiment of the present invention, the current spreading layer 21 is formed with a thickness of about 2 nm to about 100 nm. The thickness of 2 nm is a minimum thickness so that a single layer of CNT or graphene can be formed, and thickness of 100 nm is a maximum thickness so that the transmittance can be maintained to be 80% or more.

The first electrodes 22a are formed with a certain pattern on the current spreading layer 21, and the second electrodes 23 are formed on the current spreading layer 21 so that spaces between the first electrodes 22a are filled with the second electrodes 23. As illustrated in FIG. 2A, the first electrodes 22a are constructed in a rod shape where rods are arranged at a certain interval, and the cross section may be in a triangular shape, a circular shape, or any others.

The first electrodes 22a are formed to inject current into the semiconductor layer 10 or to transport current flowing from the semiconductor layer 10 to an external portion. The first electrodes 22a are formed with a material having high conductivity so as to be in ohmic contact with the semiconductor layer 10.

The second electrode 23 is formed on the current spreading layer 21 so that the spaces between the rod-shaped first electrodes 22a are filled with the second electrode 23. The second electrode 23 is formed with a material having high transmittance so as to emit the light, particularly, the light in a UV wavelength range incident from the semiconductor layer 10 to an external portion.

In the case where the above-described transparent electrode 20 is applied to an LED, the current flowing through the first electrodes 22a is allowed to spread from the current spreading layer 21 to the entire surface of the semiconductor layer 10 to be injected into the semiconductor layer 10. At this time, although the conductivity of the second electrode is lower than that of the first electrode 22a, since the second electrode 23 has a higher conductivity than that of an insulating material, some of the current flowing into the first electrodes 22a is allowed to flow through the second electrode 23 into the current spreading layer 21.

On the other hand, most of the light incident from the semiconductor layer 10 to the transparent electrode 20 is emitted through the second electrode 23 having high transmittance to an external portion. In the case where the first electrode 22a is formed with a transparent material, some of the light is emitted through the first electrodes 22a to an external portion.

As described above, in the embodiment of the present invention, the transparent electrode 20 is formed by using the first electrode 22a for improving the ohmic characteristic (conductivity characteristic) and the second electrode 23 for improving the transmittance characteristic. In order to satisfy the characteristics, the first electrode 22a is formed with a material having low transmittance and high conductivity, that is, a material having low band gap energy and low contact resistance in comparison to the second electrode 23, and the second electrode 23 is formed with a material having low conductivity and high transmittance, that is, a material having high band gap energy and high contact resistance in comparison to the first electrode 22a.

In the embodiment of the present invention, the first electrodes 22a are formed by using a material having a band gap energy of 4.5 eV or less and a contact resistance of 10⁻² Ωcm⁻² or less (for example, ITO (3.5 eV to 4.3 eV), ZnO (3.37 eV), AZO (3.36 eV), IZO (3.0 eV), GZO (3.51 eV), SnO (2.7 eV to 3.4 eV), NiO (3.4 eV to 4.3 eV), TiO₂ (3.2 eV), CdO (2.2 eV), and all metals). However, it should be noted that the present invention is not limited to the material. In this case, it is preferable that, when the first electrode 22a is formed by using a material having high conductivity and low transmittance (for example, a metal material), the area of the first electrode 22a is as small as possible so as not to influence the total transmittance.

In addition, in the embodiment of the present invention, the second electrode 23 is formed by using a material having a band gap energy exceeding 4.5 eV and a conductivity of 10⁻⁹ Ω⁻cm⁻¹ (for example, Ga₂O₃ (5.1 eV), Al₂O₃ (7.0 eV), SiO₂ (8.9 eV), MgO (7.8 eV), AlN (6.2 eV), and all wide-bandwidth transparent electrode materials having conductivity). However, it should be noted that the present invention is not limited to the material.

On the other hand, it should be noted that the semiconductor layer 10 includes all kinds of materials where electric charges can move as well as an inorganic semiconductor layer and an organic semiconductor layer. The inorganic semiconductor layer includes a single-element semiconductor constructed with a single element such as Si or Ge. In addition, the inorganic semiconductor layer includes a compound semiconductor layer such as a nitride based compound semiconductor layer (GaN, AlGaN, InN, InGaN, AlN, and the like) and an oxide based compound semiconductor layer (GaO, ZnO, CoO, IrO₂, Rh₂O₃, Al₂O₃, SnO, and the like).

The inorganic semiconductor layer includes a layer of a material constituting an electron (hole) injection layer and an electron (hole) transport layer of an OLED (organic light emitting diode).

On the other hand, it is preferable that a surface of the semiconductor layer 10 where the semiconductor layer 10 is in contacted with the transparent electrode 20 is doped as a p type or an n type in order to improve the conductivity of the semiconductor layer 10.

FIG. 2B is a diagram illustrating a configuration of a transparent electrode 20 according to another embodiment of the present invention and a configuration of a semiconductor device including the transparent electrode 20.

In the example illustrated in FIG. 2B, a current spreading layer 21 is formed on a semiconductor layer 10; a first electrode 22b is formed with a lattice pattern on the current spreading layer 21; and second electrodes 23 are formed on the current spreading layer 21 so that spaces between the first electrodes 22b are filled with the second electrodes 23. The materials used for the current spreading layer 21, the first electrode 22b, and the second electrodes 23 are the same as those of the above-described example, and thus, the detailed description thereof is omitted.

In addition to the embodiments illustrated in FIGS. 2A and 2B, any modified examples of the transparent electrode 20 formed by using electrodes having different conductivity and transmittance are included in the scope of the present invention.

For example, in the above-described example illustrated in FIG. 2A, a plurality of the rod-shaped first electrodes 22a are arranged with a certain pattern. However, a transparent electrode 20 may be constructed where a single first electrode is formed in a rod shape on the current spreading layer 21 and a second electrode 23 is formed on the current spreading layer 21 so that spaces around the first electrodes are filled with the second electrode 23.

In the above-described embodiments, the current spreading layer 21 is formed on the semiconductor layer 10, and the first electrodes 22a or 22b and the second electrodes 23 are formed on the current spreading layer 21. However, since the current spreading layer 21 is provided in order to improve only the current spreading efficiency, the current spreading layer 21 may be omitted in the transparent electrode 20. In this case, first electrodes 22c and second electrodes 23 are directly formed on the semiconductor layer 10, and current can be allowed to spread into the entire semiconductor layer 10 through the second electrodes 23 which are in contact with the first electrodes 22c (refer to (a) of FIG. 2C).

In a modified example of the present invention, as illustrated in (b) of FIG. 2C, first electrodes 22d are formed on a semiconductor layer 10 so that the first electrodes 22d are in direct contact with the semiconductor layer 10, and a current spreading layer 21-1 is formed on the surface of the semiconductor layer 10 and the surfaces of the first electrodes 22d. At this time, second electrodes 23 are formed so that spaces between the first electrodes 22d are filled with the second electrodes 23. As illustrated in (b) of FIG. 2C, the second electrodes 23 are not in contact with the first electrodes 22d and the semiconductor layer 10, but the second electrodes 23 are in contact with only the current spreading layer 21-1.

In another modified example the present invention, as illustrated in (c) of FIG. 2C, a current spreading layer 21-2 is formed on a semiconductor layer 10, and first electrodes 22e are formed on the current spreading layer 21-2. After a current spreading layer 21-2 constructed with the same material as the current spreading layer 21-2 is additionally formed on the surfaces of the first electrodes 22e, second electrodes 23 are formed in the same manner as illustrated in (b) of FIG. 2C so that spaces between the first electrodes 22e are filled with the second electrodes 23.

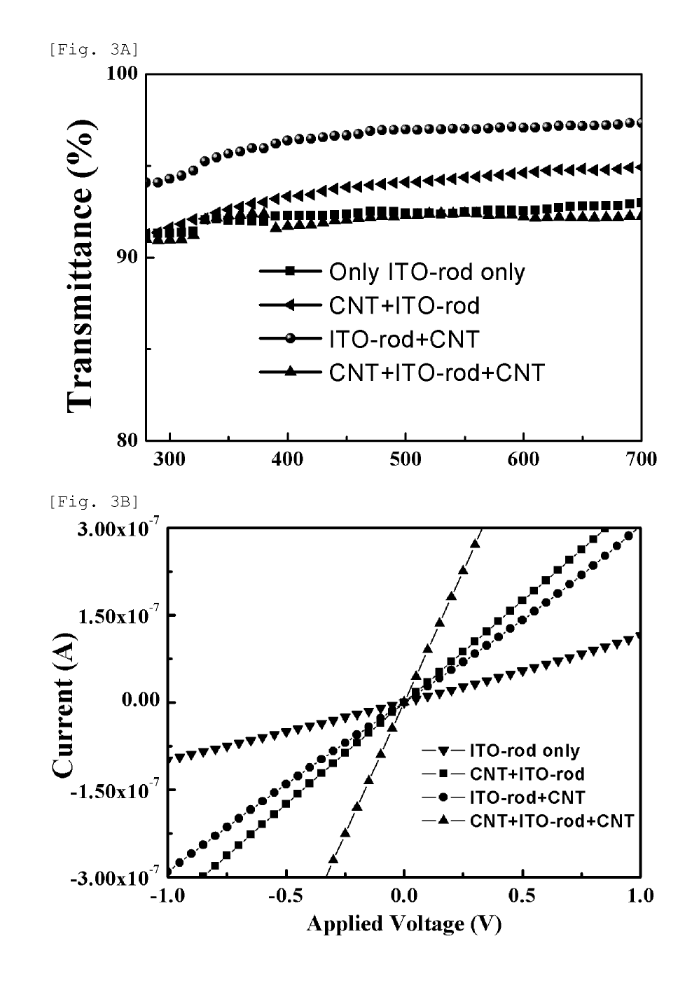

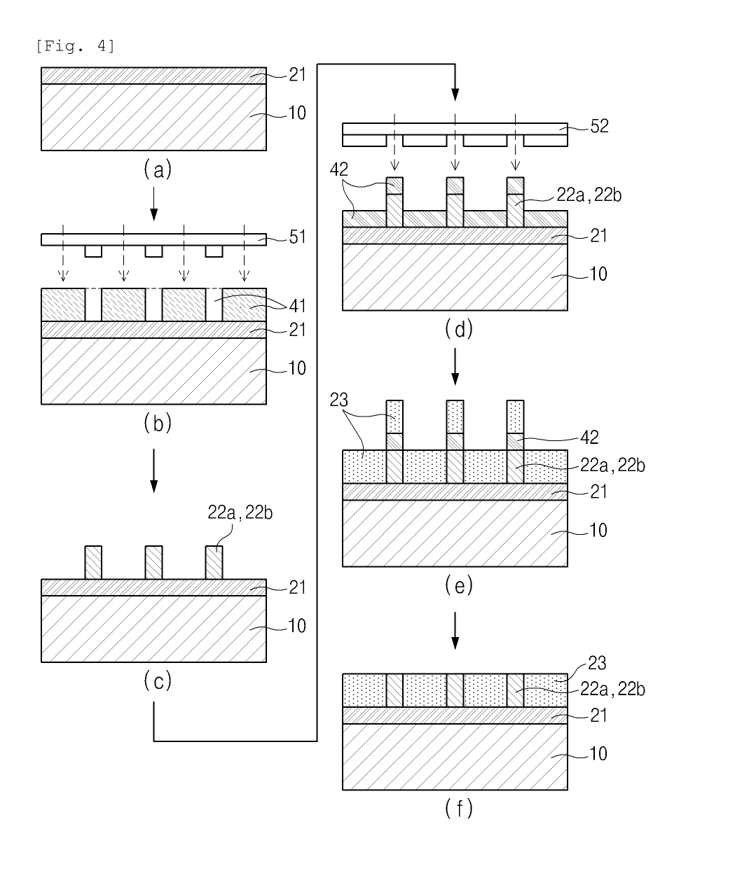

FIG. 3A is a graph illustrating measured data of transmittance of the transparent electrodes 20 according to the embodiments and modified examples of the present invention; and FIG. 3B is a graph illustrating measured data of ohmic characteristic of the transparent electrodes 20 according to the embodiments and modified examples of the present invention.

In the graphs illustrated in FIGS. 3A and 3B, the semiconductor layer 10 is formed by using a p-GaN layer; the first electrodes 22a, 22c, 22d, and 22e are formed by using ITO electrodes; the current spreading layers 21, 21-1, and 21-2 are formed by using a CNT layer; and the second electrodes 23 are formed by using Ga₂O₃. The measurement result of the embodiment illustrated in FIG. 2A is indicated by “CNT+ITO-rod”; the measurement result of the embodiment illustrated in (a) of FIG. 2C is indicated by “Only ITO-rod”; the measurement result of the embodiment illustrated in (b) of FIG. 2C is indicated by “ITO-rod+CNT”; and the measurement result of the embodiment illustrated in (c) of FIG. 2C is indicated by “CNT+ITO-rod+CNT”.

First, referring to FIG. 3A, it can be understood that, as the measurement results of transmittance in all the embodiments, good transmittance of 90% or more with respect o the light in a UV wavelength range of 300 nm can be obtained. In addition, it can be understood that, even in the case of the embodiment (“Only ITO-rod”) having the lowest transmittance illustrated in (a) of FIG. 2C, the transmittance is 90% or more.

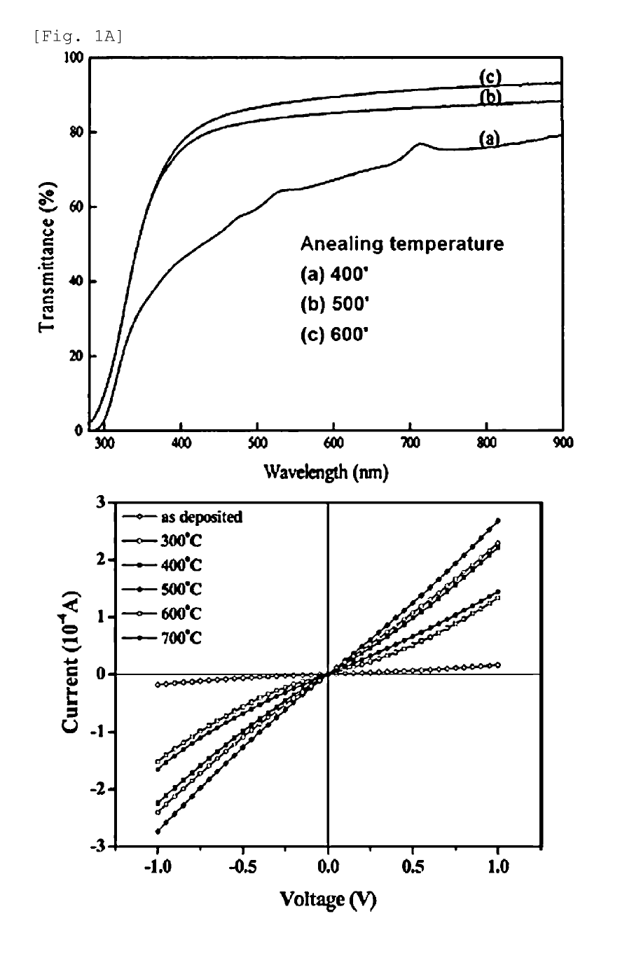

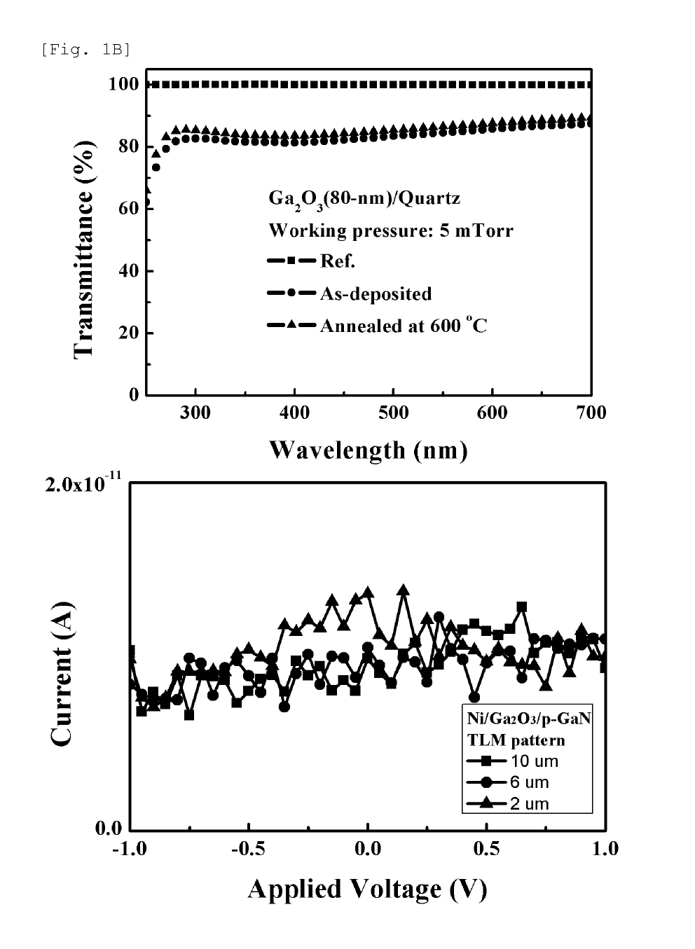

It can be understood from the measurement result that the transmittance is greatly improved in comparison to the ITO transparent electrode in the related art illustrated in FIG. 1A where the transmittance with respect to the light in a wavelength range 300 nm is in a range of 20% to 30%.

In addition, referring to FIG. 3B, it can be understood that the transparent electrodes according to all the embodiments of the present invention has high transmittance and good ohmic characteristic. Particularly, the transparent electrode according to the embodiment (“CNT+ITO-rod+CNT”) illustrated in (c) of FIG. 2C has the best conductivity.

The graph of FIG. 3B illustrates the measurement result of the case of using a TLM (transfer length method) pattern having an interval of 200 μm which is 100 times the interval of about 2 μm of the pattern in the related art illustrated in FIG. 1A, so that current measured in the case is relatively small. Therefore, it can be understood by the ordinarily skilled that, if the interval of the TLM pattern in the case of the present invention is set to be about 2 μm which is equal to the interval of the pattern in the related art, larger current than the current illustrated in FIG. 3B may be obtained.

Hereinbefore, the transparent electrodes according to the embodiments of the present invention and the semiconductor devices including the transparent electrodes are described.

Hereinafter, a meted for forming the transparent electrodes 20 illustrated in FIGS. 2A and 2B will be described with reference to FIG. 4.

Referring to FIG. 4, a current spreading layer 21 is formed on a semiconductor layer 10 where a transparent electrode 20 is to be formed (refer to (a) of FIG. 4). As described above, it is preferable that the current spreading layer 21 is formed with a thickness of 2 nm to 100 nm by using CNT or graphene. The current spreading layer 21 can be formed by coating the semiconductor layer 10 with a solution containing the CNT or graphene and evaporating the solution.

Next, photoresist 41 is formed on the current spreading layer 21, and exposure and development are performed by using a mask 51, so that the photoresist is removed from a pattern region where first electrodes 22a or 22b are to be formed (refer to (b) of FIG. 4). Next, a pattern of the first electrodes 22a or 22b is formed by depositing with a material for the first electrodes 22a or 22b (refer to (c) of FIG. 4). At this time, as illustrated in FIG. 2A, the pattern of the first electrodes 22a may be formed in a rod shape with a certain spacing; as illustrated in FIG. 2B, the pattern of the first electrodes 22b may be formed in a lattice shape; and other patterns of the first electrodes may be formed.

After the pattern of the first electrodes 22a or 22b is formed, photoresist 43 is formed on the current spreading layer 21 and the pattern of the first electrodes 22a or 22b, and exposure and development are performed by using a mask 52, so that the photoresist 42 is removed from a pattern region where second electrodes 23 are to be formed on the current spreading layer 21 (refer to (d) of FIG. 4). Next, the second electrodes 23 with which spaces between the first electrodes 22a or 22b are filled are formed by depositing a material for the second electrodes 23 (refer to (e) of FIG. 4).

Next, the photoresist 42 formed on the first electrodes 22a or 22b and the material for the second electrodes 23 are removed, so that the above-described transparent electrodes 20 are obtained.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

1. A transparent electrode comprising first and second electrodes which are in contact with a surface of a semiconductor layer and have different transmittance and conductivity.

2. The transparent electrode according to claim 1, wherein the conductivity of the first electrode is higher than that of the second electrode, and the transmittance of the second electrode is higher than that of the first electrode.

3. The transparent electrode according to claim 1, wherein the first electrodes are formed with a certain pattern, and the second electrodes are formed so that spaces between first electrodes are filled with the second electrodes.

4. The transparent electrode according to claim 3, wherein the first electrodes are formed with a pattern where a plurality of conductive rods are arranged at a certain interval.

5. The transparent electrode according to claim 3, wherein the first electrodes are formed with a lattice pattern.

6. The transparent electrode according to claim 1, further comprising a current spreading layer which is formed on a surface of the transparent electrode which is in contact with the semiconductor layer, wherein the first electrodes and the second electrodes are formed to be in contact with the current spreading layer.

7. The transparent electrode according to claim 6, wherein the current spreading layer is formed on surfaces of the first electrodes, and the second electrodes are formed so that the second electrodes are in contact with the current spreading layer and spaces between the first electrodes are filled with the second electrodes.

8. The transparent electrode according to claim 6, wherein the current spreading layer is formed by using CNT (carbon nano tube) or graphene.

9. The transparent electrode according to claim 1, further comprising a current spreading layer which is formed on surfaces of the first electrodes which are in contact with the semiconductor layer and on surface of the semiconductor layer, wherein the second electrodes are formed so that the second electrodes are in contact with the current spreading layer and spaces between the first electrodes are filled with the second electrodes.

10. The transparent electrode according to claim 1, wherein the first electrodes are formed in a direction perpendicular to the semiconductor layer to be in contact with the semiconductor layer, and the second electrodes are formed to be in contact with the semiconductor layer so that spaces between the first electrodes are filled with the second electrodes.

11. A semiconductor device comprising the transparent electrode according to claim 1.

12. A method for forming a transparent electrode, comprising:
(a) forming first electrodes on a semiconductor layer; and
(b) forming second electrodes having transmittance and conductivity which are different from those of the first electrodes.

13. The method according to claim 12, wherein the conductivity of the first electrode is higher than that of the second electrode, and the transmittance of the second electrode is higher than that of the first electrode.

14. The method according to claim 12,
wherein, in the (a) forming of the first electrodes, the first electrodes are formed with a certain pattern, and
wherein, in the (b) forming of the second electrodes, the second electrodes are formed so that spaces between first electrodes are filled with the second electrodes.

15. The method according to claim 14, wherein, in the (a) forming of the first electrodes, the first electrodes are formed with a pattern where a plurality of conductive rods are arranged at a certain interval.

16. The method according to claim 14, wherein, in the (a) forming of the first electrodes, the first electrodes are formed with a lattice pattern.

17. The method according to claim 12, further comprising, before the (a) forming of the first electrodes, forming a current spreading layer on a surface of the transparent electrode which is in contact with the semiconductor layer, wherein the first electrodes and the second electrodes are formed to be in contact with the current spreading layer.

18. The method according to claim 17,
wherein, in the (a) forming of the first electrodes, after the first electrodes are formed to be in contact with the current spreading layer, the current spreading layer is additionally formed on surfaces of the first electrodes, and
wherein, in the (b) forming of the second electrodes, the second electrodes are formed so that the second electrodes are in contact with the current spreading layer and spaces between the first electrodes are filled with the second electrodes.

19. (canceled)

20. The method according to claim 12,
wherein, in the (a) forming of the first electrodes, the first electrodes are formed to be in contact with the semiconductor layer,
wherein, the method further comprises, between the (a) forming of the first electrode and the (b) forming of the second electrode, forming a current spreading layer on the surfaces of the first electrodes and on the surface of the semiconductor layer, and
wherein, in the (b) forming of the second electrodes, the second electrodes are formed so that the second electrodes are in contact with the current spreading layer and spaces between the first electrodes are filled with the second electrodes.

21. The method according to claim 12,
wherein, in the (a) forming of the first electrodes, the first electrodes are formed in a direction perpendicular to the semiconductor layer to be in contact with the semiconductor layer, and
wherein, in the (b) forming of the second electrodes, the second electrodes are formed to be in contact with the semiconductor layer so that spaces between the first electrodes are filled with the second electrodes.
